(19) United States
(12) Patent Application Publication
(10) Pub. No.: US 2026/0099645 A1
(43) Pub. Date: Apr. 9, 2026

(54) PREDICTIVE COLLISION ANALYSIS BASED ON INPUTS FROM A GAMING CONTROLLER

(71) Applicant: FARO Technologies, Inc., Lake Mary, FL (US)

(72) Inventors: Derik J. White, Ocean Park, WA (US); Noreen Charlton, Avon, OH (US); Russell Boynton, Manchester, NH (US); Paul Hetherington, Kamloops (CA)

(21) Appl. No.: 19/351,698

(22) Filed: Oct. 7, 2025

Related U.S. Application Data
(63) Continuation of application No. PCT/US24/23985, filed on Apr. 11, 2024.
(60) Provisional application No. 63/459,074, filed on Apr. 13, 2023.

(51) Int. Cl. G06F 30/20; G01S 7/481; G01S 17/42; G01S 17/931; G06F 3/02; G06F 3/0354; G06F 3/038; G06T 19/00; G08G 1/16

(52) U.S. Cl. CPC G06F 30/20; G01S 7/4813; G01S 7/4817; G01S 17/42; G01S 17/931; G06F 3/0227; G06F 3/03543; G06F 3/038; G06T 19/006; G08G 1/16; G06T 2200/24; G06T 2210/21; G06T 2210/56

(57) ABSTRACT

Examples described herein provide a method for performing a predictive collision analysis. The method includes initiating the predictive collision analysis to be performed on a processing system, the predictive collision analysis being performed using a plurality of prediction properties. The method further includes setting a prediction property of the plurality of prediction properties using a signal received from an electronic steering wheel communicatively coupled to the processing system. The method further includes performing, by the processing system, the predictive collision analysis using the prediction property.

### CROSS-REFERENCE TO RELATED APPLICATION

This application is a continuation of PCT Application Serial No. PCT/US24/23985, filed Apr. 11, 2024, and entitled “PREDICTIVE COLLISION ANALYSIS BASED ON INPUTS FROM A GAMING CONTROLLER,” the contents of which are incorporated by reference herein in their entirety, and this application claims the benefit of U.S. Provisional Patent Application Ser. No. 63/459,074, filed Apr. 13, 2023 and entitled “PREDICTIVE COLLISION ANALYSIS BASED ON INPUTS FROM A GAMING CONTROLLER,” the contents of which are incorporated by reference herein in their entirety.

### BACKGROUND

The subject matter disclosed herein relates to a system for predicting or simulating a vehicle collision. The electronic model makes use of a three-dimensional (3D) coordinate measurement device, such as a laser scanner time-of-flight (TOF) coordinate measurement device referred to as a “TOF scanner,” “3D laser scanner,” or “laser scanner.” A 3D laser scanner of this type steers a beam of light to a non-cooperative target such as a diffusely scattering surface of an object. A distance meter in the device measures a distance to the object, and angular encoders measure the angles of rotation of two axles in the device. The measured distance and two angles enable a processor in the device to determine the 3D coordinates of the target.

A TOF laser scanner is a scanner in which the distance to a target point is determined based on the speed of light in air between the scanner and a target point. Laser scanners are typically used for scanning closed or open spaces such as interior areas of buildings, industrial installations and tunnels. They are also be used, for example, in industrial applications and accident reconstruction applications. A laser scanner optically scans and measures objects in a volume around the scanner through the acquisition of data points representing object surfaces within the volume. Such data points are obtained by transmitting a beam of light onto the objects and collecting the reflected or scattered light to determine the distance, two-angles (i.e., an azimuth and a zenith angle), and optionally a gray-scale value. This raw scan data is collected, stored and sent to a processor or processors to generate a 3D image representing the scanned area or object.

### BRIEF DESCRIPTION

In one embodiment, a method for performing a predictive collision analysis is provided. The method includes initiating the predictive collision analysis to be performed on a processing system, the predictive collision analysis being performed using a plurality of prediction properties. The method further includes setting a first prediction property of the plurality of prediction properties using a first signal received from an electronic steering wheel communicatively coupled to the processing system. The method further includes performing, by the processing system, the predictive collision analysis using the first prediction property.

In another embodiment, a system is provided. The system includes a gaming controller to generate a signal and a processing system communicatively coupled to the gaming controller to receive the signal from the gaming controller. The processing system includes a memory comprising computer readable instructions, and a processing device for executing the computer readable instructions. The computer readable instructions control the processing device to perform operations for performing a predictive collision analysis. The operations include initiating the predictive collision analysis to be performed on the processing system, the predictive collision analysis being performed using a plurality of prediction properties. The operations further include setting a prediction property of the plurality of prediction properties using the signal generated by the gaming controller. The operations further include performing, by the processing system, the predictive collision analysis using the prediction property.

In another embodiment, a system is provided. The system includes a keyboard to generate a first signal, a pointing device to generate a second signal, and a processing system communicatively coupled to the keyboard to receive the first signal from the keyboard and communicatively coupled to the mouse to receive the second signal from the mouse. The processing system includes a memory comprising computer readable instructions and a processing device for executing the computer readable instructions. The computer readable instructions control the processing device to perform operations for performing a predictive collision analysis. The operations include initiating the predictive collision analysis to be performed on the processing system, the predictive collision analysis being performed using a plurality of prediction properties. The operations further include setting a first prediction property of the plurality of prediction properties using the first signal generated by the keyboard, the first signal being generated by a user manipulating keys of the keyboard to cause the first signal to mimic a first behavior of the vehicle. The operations further include setting a second prediction property of the plurality of prediction properties using the second signal generated by the pointing device, the second signal being generated by the user manipulating the pointing device to cause the second signal to mimic a second behavior of the vehicle. The operations further include performing, by the processing system, the predictive collision analysis using the first prediction property and the second prediction property.

The above features and advantages, and other features and advantages, of the disclosure are readily apparent from the following detailed description when taken in connection with the accompanying drawings.

### BRIEF DESCRIPTION OF DRAWINGS

The specifics of the exclusive rights described herein are particularly pointed out and distinctly claimed in the claims at the conclusion of the specification. The foregoing and other features and advantages of one or more embodiments described herein are apparent from the following detailed description taken in conjunction with the accompanying drawings in which:

FIG. 1 is a perspective view of a laser scanner according to one or more embodiments described herein;

FIG. 2 is a side view of the laser scanner illustrating a method of measurement according to one or more embodiments described herein;

FIG. 3 is a schematic illustration of the optical, mechanical, and electrical components of the laser scanner according to one or more embodiments described herein;

FIG. 4 is a schematic illustration of the laser scanner of FIG. 1 according to one or more embodiments described herein;

FIG. 5 is a schematic illustration of a processing system for predictive collision analysis based on inputs from a gaming controller according to one or more embodiments described herein;

FIG. 6 is a flow diagram of a method for predictive collision analysis based on inputs from a gaming controller according to one or more embodiments described herein;

FIG. 7A, FIG. 7B, FIG. 7C, FIG. 7D, FIG. 7E, and FIG. 7F are interfaces showing a real-time display of the predictive collision analysis according to one or more embodiments described herein;

FIG. 8A, FIG. 8B, FIG. 8C, FIG. 8D, FIG. 8E, and FIG. 8F are interfaces showing a real-time display of the predictive collision analysis according to one or more embodiments described herein;

FIG. 9 is an interface showing a real-time display of the predictive collision analysis according to one or more embodiments described herein;

FIG. 10 is an interface showing a real-time display of the predictive collision analysis according to one or more embodiments described herein; and

FIG. 11 is a schematic illustration of a processing system for implementing the presently described techniques according to one or more embodiments described herein.

The detailed description explains embodiments of the disclosure, together with advantages and features, by way of example with reference to the drawings.

### DETAILED DESCRIPTION

Embodiments described herein provide for predictive collision analysis based on inputs from a gaming controller.

Three-dimensional (3D) coordinate measurement devices, such as laser scanners, are used to captured 3D data about an environment, such as the location where a vehicle collision (or collisions) has occurred for example. The 3D data is presented on a device, such as a smartphone, tablet, heads-up display, etc., as a graphical representation. In some cases, the graphical representation is a point cloud, which is a collection of points (e.g., the 3D data), where each point is defined by coordinate (x, y, z).

One use case for 3D data is for predictive collision analysis. For example, when an incident (e.g., a collision between vehicles) occurs, investigators and forensic experts desire to establish facts and document the incident, which is useful for collision reconstruction, crime and fire investigation, courtroom presentation creation, and/or the like including combinations and/or multiples thereof. Accordingly, a 3D coordinate measurement device is used to document an environment where the incident occurred. For example, the 3D coordinate measurement device collects 3D data about the environment so the environment is virtually/digitally recreated and used for collision reconstruction and the like.

The data acquired by the 3D coordinate measurement device is used by a user in a simulation collision analysis in an attempt to recreate the vehicle collision. Depending on the complexity of the simulation, such as the number of vehicles involved and environmental conditions for example, the recreation of the vehicle collision is a time consuming process that involved many iterations of manually changing parameters of the vehicles and comparing the results to actual data. While existing collision simulation or prediction systems are suitable for their intended purposes, what is needed is a collision simulation or prediction system having certain features of embodiments described herein.

Predictive collision analysis is the process of predicting or simulating an incident using data about the environment where the incident occurred (e.g., 3D data collected by the 3D coordinate measurement device) and/or prediction properties. Non-limiting examples of such incidents include a collision between or among vehicles, a collision between a vehicle and a pedestrian, a collision between a vehicle and a stationary object, and/or the like including combinations and/or multiples thereof. A vehicle includes, but is not limited to, a car, truck, van, bus, boat/ship, airplane, bicycle, motorcycle, and/or the like including combinations and/or multiples thereof. Prediction properties are user defined, estimated/calculated, or measured (e.g., from a vehicle's event data recorder). For example, a vehicle's event data recorder (or “black box”) data is used in the simulation to define prediction properties; however, such event data records often records a few seconds of data before the crash, which is not a long enough duration to be used to create the events that led up to the collision. The terms “predicting” and “simulating” are used interchangeably herein, except where noted otherwise.

In some cases, the predictive collision analysis is used for reconstruction an incident that has occurred in the past. Predictive collision analysis uses a virtual environment corresponding to a real-world environment to simulate the incident and uses one or more virtual vehicles to simulate real-world vehicles involved in the incident. Predictive collision analysis is useful for evaluating an incident, such as to determine liability or understand how the incident occurred. In other cases, the predictive collision analysis is used for evaluating an environment for potential incidents that might occur in the future. This is useful for evaluating environments, such as before construction, roadwork, etc. is performed to minimize the likelihood of incidents occurring. For example, if a new interchange is being designed, predictive collision analysis is performed to evaluate the new interchange design to determine a likelihood of different incidents occurring. One example of a model used for predictive collision analysis is the multibody animation and simulation system (MASS) simulation model, described in a whitepaper entitled “The MASS Simulation Model” by Mike Kennedy, Paul Hetherington, and Bob Scurlock, which is incorporated by reference herein in its entirety.

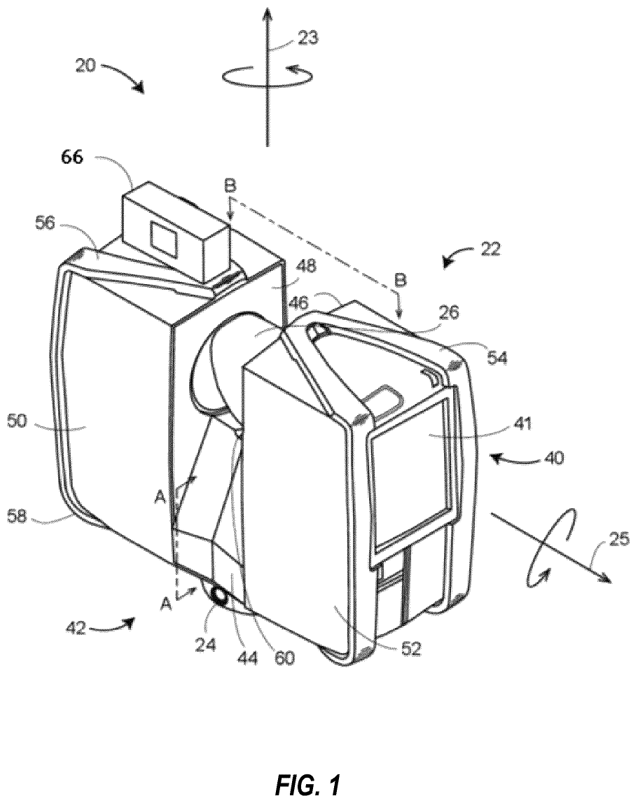

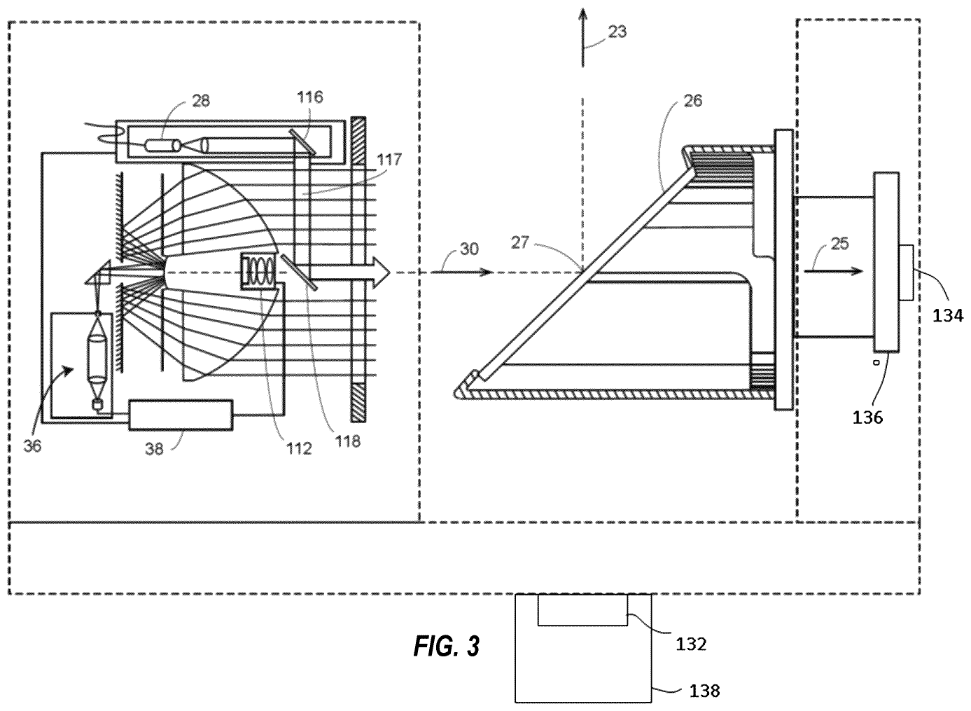

Referring now to FIG. 1-3, a 3D coordinate measurement device, such as a laser scanner 20, is shown for optically scanning and measuring the environment surrounding the laser scanner 20 according to one or more embodiments described herein. The laser scanner 20 has a measuring head 22 and a base 24. The measuring head 22 is mounted on the base 24 such that the laser scanner 20 is rotated about a vertical axis 23. In one embodiment, the measuring head 22 includes a gimbal point 27 that is a center of rotation about the vertical axis 23 and a horizontal axis 25. The measuring head 22 has a rotary mirror 26, which is rotated about the horizontal axis 25. The rotation about the vertical axis is about the center of the base 24. The terms vertical axis and horizontal axis refer to the scanner in its normal upright position. It is possible to operate a 3D coordinate measurement device on its side or upside down, and so to avoid confusion, the terms azimuth axis and zenith axis are substituted for the terms vertical axis and horizontal axis, respectively. The term pan axis or standing axis is also used as an alternative to vertical axis.

The measuring head 22 is further provided with an electromagnetic radiation emitter, such as light emitter 28, for example, that emits an emitted light beam 30. In one embodiment, the emitted light beam 30 is a coherent light beam such as a laser beam. The laser beam has a wavelength range of approximately 300 to 1500 nanometers, for example 790 nanometers, 905 nanometers, 1550 nm, or less than 400 nanometers. It should be appreciated that other electromagnetic radiation beams having greater or smaller wavelengths are also used. The emitted light beam 30 is amplitude or intensity modulated, for example, with a sinusoidal waveform or with a rectangular waveform. The emitted light beam 30 is emitted by the light emitter 28 onto a beam steering unit, such as mirror 26, where it is deflected to the environment. A reflected light beam 32 is reflected from the environment by an object 34. The reflected or scattered light is intercepted by the rotary mirror 26 and directed into a light receiver 36. The directions of the emitted light beam 30 and the reflected light beam 32 result from the angular positions of the rotary mirror 26 and the measuring head 22 about the axes 25 and 23, respectively. These angular positions in turn depend on the corresponding rotary drives or motors.

Coupled to the light emitter 28 and the light receiver 36 is a controller 38. The controller 38 determines, for a multitude of measuring points X, a corresponding number of distances d between the laser scanner 20 and the points X on object 34. The distance to a particular point X is determined based at least in part on the speed of light in air through which electromagnetic radiation propagates from the device to the object point X. In one embodiment the phase shift of modulation in light emitted by the laser scanner 20 and the point X is determined and evaluated to obtain a measured distance d.

The speed of light in air depends on the properties of the air such as the air temperature, barometric pressure, relative humidity, and concentration of carbon dioxide. Such air properties influence the index of refraction n of the air. The speed of light in air is equal to the speed of light in vacuum c divided by the index of refraction. In other words, cₐᵢᵣ=c/n. A laser scanner of the type discussed herein is based on the time-of-flight (TOF) of the light in the air (the round-trip time for the light to travel from the device to the object and back to the device). Examples of TOF scanners include scanners that measure round trip time using the time interval between emitted and returning pulses (pulsed TOF scanners), scanners that modulate light sinusoidally and measure phase shift of the returning light (phase-based scanners), as well as many other types. A method of measuring distance based on the time-of-flight of light depends on the speed of light in air and is therefore easily distinguished from methods of measuring distance based on triangulation. Triangulation-based methods involve projecting light from a light source along a particular direction and then intercepting the light on a camera pixel along a particular direction. By knowing the distance between the camera and the projector and by matching a projected angle with a received angle, the method of triangulation enables the distance to the object to be determined based on one known length and two known angles of a triangle. The method of triangulation, therefore, does not directly depend on the speed of light in air.

In one mode of operation, the scanning of the volume around the laser scanner 20 takes place by rotating the rotary mirror 26 relatively quickly about axis 25 while rotating the measuring head 22 relatively slowly about axis 23, thereby moving the assembly in a spiral pattern. In an exemplary embodiment, the rotary mirror rotates at a maximum speed of 5820 revolutions per minute. For such a scan, the gimbal point 27 defines the origin of the local stationary reference system. The base 24 rests in this local stationary reference system.

In addition to measuring a distance d from the gimbal point 27 to an object point X, the laser scanner 20 also collects gray-scale information related to the received optical power (equivalent to the term “brightness.”) The gray-scale value is determined at least in part, for example, by integration of the bandpass-filtered and amplified signal in the light receiver 36 over a measuring period attributed to the object point X.

The measuring head 22 includes a display device 40 integrated into the laser scanner 20. The display device 40 includes a graphical touch screen 41, as shown in FIG. 1, which allows the operator to set the parameters or initiate the operation of the laser scanner 20. For example, the screen 41 has a user interface that allows the operator to provide measurement instructions to the device, and the screen also displays measurement results.

The laser scanner 20 includes a carrying structure 42 that provides a frame for the measuring head 22 and a platform for attaching the components of the laser scanner 20. In one embodiment, the carrying structure 42 is made from a metal such as aluminum. The carrying structure 42 includes a traverse member 44 having a pair of walls 46, 48 on opposing ends. The walls 46, 48 are parallel to each other and extend in a direction opposite the base 24. Shells 50, 52 are coupled to the walls 46, 48 and cover the components of the laser scanner 20. In the exemplary embodiment, the shells 50, 52 are made from a plastic material, such as polycarbonate or polyethylene for example. The shells 50, 52 cooperate with the walls 46, 48 to form a housing for the laser scanner 20.

On an end of the shells 50, 52 opposite the walls 46, 48 a pair of yokes 54, 56 are arranged to partially cover the respective shells 50, 52. In the exemplary embodiment, the yokes 54, 56 are made from a suitably durable material, such as aluminum for example, that assists in protecting the shells 50, 52 during transport and operation. The yokes 54, 56 each includes a first arm portion 58 that is coupled, such as with a fastener for example, to the traverse 44 adjacent the base 24. The arm portion 58 for each yoke 54, 56 extends from the traverse 44 obliquely to an outer corner of the respective shell 50, 52. From the outer corner of the shell, the yokes 54, 56 extend along the side edge of the shell to an opposite outer corner of the shell. Each yoke 54, 56 further includes a second arm portion that extends obliquely to the walls 46, 48. It should be appreciated that the yokes 54, 56 are coupled to the traverse 44, the walls 46, 48 and the shells 50, 52 at multiple locations.

The pair of yokes 54, 56 cooperate to circumscribe a convex space within which the two shells 50, 52 are arranged. In the exemplary embodiment, the yokes 54, 56 cooperate to cover all of the outer edges of the shells 50, 52, while the top and bottom arm portions project over at least a portion of the top and bottom edges of the shells 50, 52. This provides advantages in protecting the shells 50, 52 and the measuring head 22 from damage during transportation and operation. In other embodiments, the yokes 54, 56 includes additional features, such as handles to facilitate the carrying of the laser scanner 20 or attachment points for accessories for example.

On top of the traverse 44, a prism 60 is provided. The prism extends parallel to the walls 46, 48. In the exemplary embodiment, the prism 60 is integrally formed as part of the carrying structure 42. In other embodiments, the prism 60 is a separate component that is coupled to the traverse 44. When the mirror 26 rotates, during each rotation the mirror 26 directs the emitted light beam 30 onto the traverse 44 and the prism 60. Due to non-linearities in the electronic components, for example in the light receiver 36, the measured distances d depend on signal strength, which are measured in optical power entering the scanner or optical power entering optical detectors within the light receiver 36, for example. In an embodiment, a distance correction is stored in the scanner as a function (possibly a nonlinear function) of distance to a measured point and optical power (generally unscaled quantity of light power sometimes referred to as “brightness”) returned from the measured point and sent to an optical detector in the light receiver 36. Since the prism 60 is at a known distance from the gimbal point 27, the measured optical power level of light reflected by the prism 60 is used to correct distance measurements for other measured points, thereby allowing for compensation to correct for the effects of environmental variables such as temperature. In the exemplary embodiment, the resulting correction of distance is performed by the controller 38.

In an embodiment, the base 24 is coupled to a swivel assembly (not shown) such as that described in commonly owned U.S. Pat. No. 8,705,012 ('012), which is incorporated by reference herein. The swivel assembly is housed within the carrying structure 42 and includes a motor 138 that is configured to rotate the measuring head 22 about the axis 23. In an embodiment, the angular/rotational position of the measuring head 22 about the axis 23 is measured by angular encoder 134.

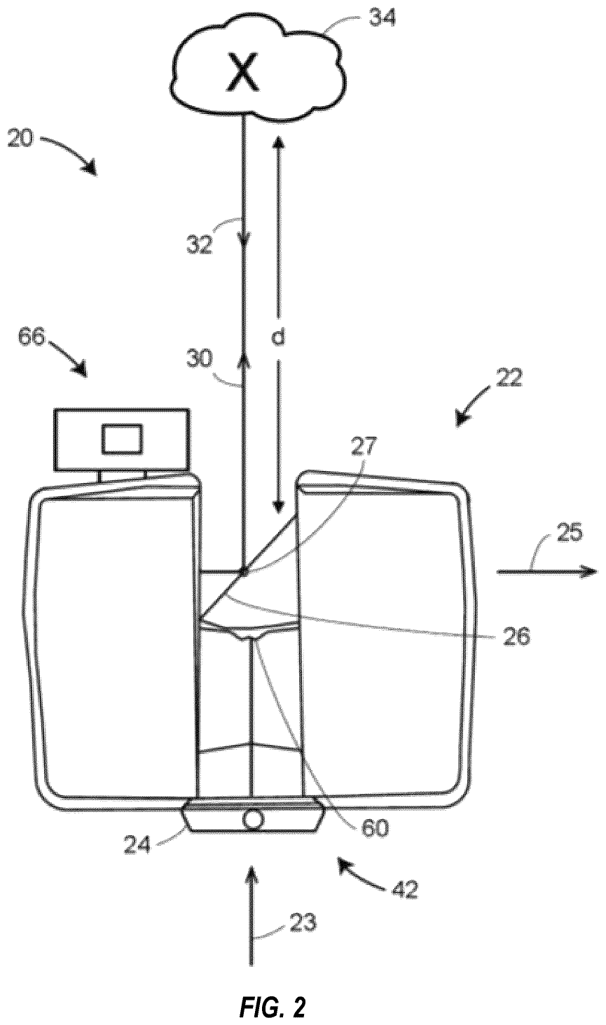

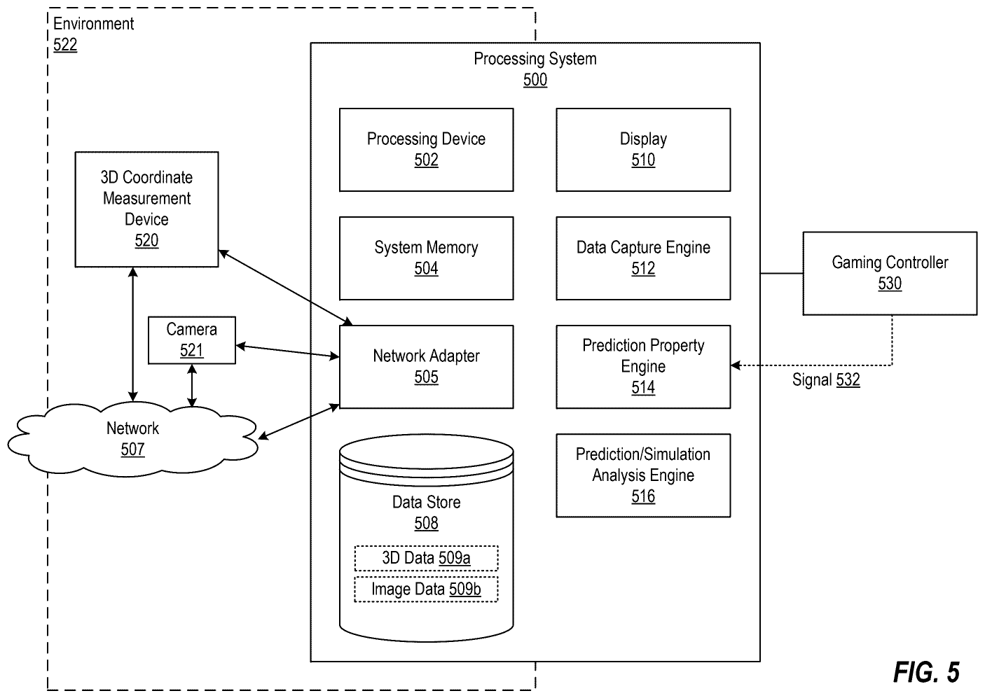

An auxiliary image acquisition device 66 is a device that captures and measures a parameter associated with the scanned area or the scanned object and provides a signal representing the measured quantities over an image acquisition area. The auxiliary image acquisition device 66 is one of a pyrometer, a thermal imager, an ionizing radiation detector, or a millimeter-wave detector, although not limited thereto. In an embodiment, the auxiliary image acquisition device 66 is a color camera with an ultrawide-angle lens, sometimes referred to as a “ultrawide-angle camera” or a “panoramic camera. ” In an embodiment, as shown in FIGS. 1 and 2, the auxiliary image acquisition device 66 is physically coupled to and/or integrated with the laser scanner 20. In another embodiment, the auxiliary image acquisition device 66 is separate from, but associated with, the laser scanner 20. For example, a camera 521 (e.g., the auxiliary image acquisition device 66) is associated with a 3D coordinate measurement device 520 (e.g., the laser scanner 20), as shown in FIG. 5.

In an embodiment, a central color camera (first image acquisition device) 112 is located internally to the scanner and has the same optical axis as the 3D scanner device. In this embodiment, the first image acquisition device 112 is integrated into the measuring head 22 and arranged to acquire images along the same optical pathway as emitted light beam 30 and reflected light beam 32. In this embodiment, the light from the light emitter 28 reflects off a fixed mirror 116 and travels to dichroic beam-splitter 118 that reflects the light 117 from the light emitter 28 onto the rotary mirror 26. In an embodiment, the mirror 26 is rotated by a motor 136 and the angular/rotational position of the mirror is measured by angular encoder 134. The dichroic beam-splitter 118 allows light to pass through at wavelengths different than the wavelength of light 117. For example, the light emitter 28 is near an infrared laser light (for example, light at wavelengths of 780 nm or 1250 nm), with the dichroic beam-splitter 118 configured to reflect the infrared laser light while allowing visible light (e.g., wavelengths of 400 to 700 nm) to transmit through. In other embodiments, the determination of whether the light passes through the beam-splitter 118 or is reflected depends on the polarization of the light. The digital camera or first image acquisition device 112 obtains two-dimensional (2D) images of the scanned area to capture color data to add to the scanned image. In the case of a built-in color camera having an optical axis coincident with that of the 3D scanning device, the direction of the camera view is easily obtained by simply adjusting the steering mechanisms of the scanner—for example, by adjusting the azimuth angle about the axis 23 and by steering the mirror 26 about the axis 25.

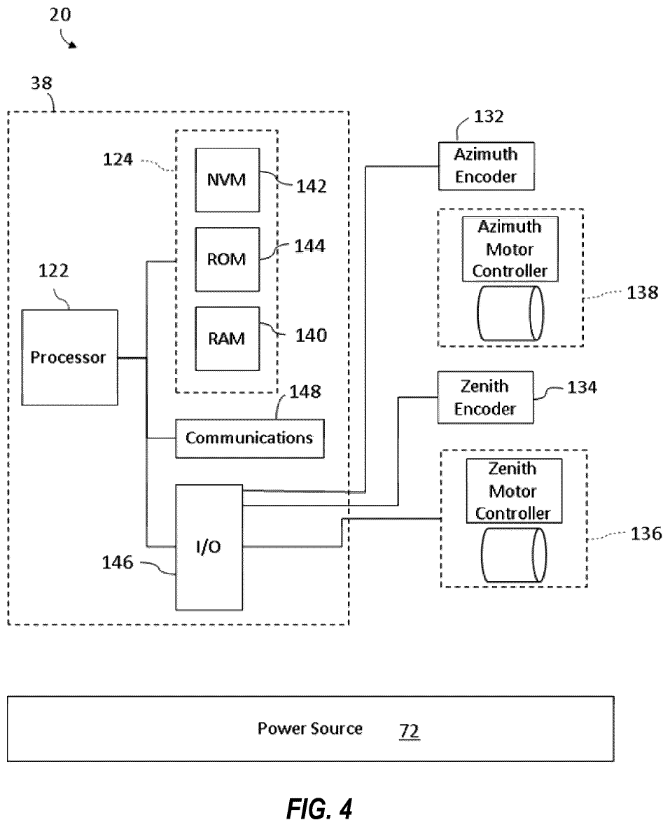

Referring now to FIG. 4 with continuing reference to FIG. 1-3, elements are shown of the laser scanner 20. Controller 38 is a suitable electronic device capable of accepting data and instructions, executing the instructions to process the data, and presenting the results. The controller 38 includes one or more processing elements 122. The processors are microprocessors, field programmable gate arrays (FPGAs), digital signal processors (DSPs), and generally any device capable of performing computing functions. The one or more processors 122 have access to memory 124 for storing information.

Controller 38 is capable of converting the analog voltage or current level provided by light receiver 36 into a digital signal to determine a distance from the laser scanner 20 to an object in the environment. Controller 38 uses the digital signals that act as input to various processes for controlling the laser scanner 20. The digital signals represent one or more laser scanner 20 data including but not limited to distance to an object, images of the environment, images acquired by a panoramic camera, angular/rotational measurements by a first or azimuth encoder 132, and angular/rotational measurements by a second axis or zenith encoder 134.

In general, controller 38 accepts data from encoders 132, 134, light receiver 36, light source or light emitter 28, and a panoramic camera and is given certain instructions for the purpose of generating a 3D point cloud of a scanned environment. Controller 38 provides operating signals to the light emitter 28, light receiver 36, panoramic camera, zenith motor 136 and azimuth motor 138. The controller 38 compares the operational parameters to predetermined variances and if a predetermined variance of the predetermined variances is exceeded, generates a signal that alerts an operator to a condition. The data received by the controller 38 is displayed on the user interface 40 coupled to controller 38. The user interface 40 is one or more LEDs (light-emitting diodes), an LCD (liquid-crystal diode) display, a CRT (cathode ray tube) display, a touch-screen display or the like. A keypad is also coupled to the user interface for providing data input to controller 38. In one embodiment, the user interface is arranged or executed on a mobile computing device that is coupled for communication, such as via a wired or wireless communications medium (e.g. Ethernet, serial, USB, Bluetooth™ or WiFi) for example, to the laser scanner 20. A power source 72 is associated with laser scanner 20, as shown in FIG. 4.

The controller 38 is also coupled to external computer networks such as a local area network (LAN) and the Internet. A LAN interconnects one or more remote computers, which are configured to communicate with controller 38 using a well-known computer communications protocol such as TCP/IP (Transmission Control Protocol/Internet Protocol), RS-232, ModBus, and/or the like including combinations and/or multiples thereof. Additional systems 20 are also connected to LAN with the controllers 38 in each of these systems 20 being configured to send and receive data to and from remote computers and other systems 20. The LAN is connected to the Internet. This connection allows controller 38 to communicate with one or more remote computers connected to the Internet.

The processors 122 are coupled to memory 124. The memory 124 includes random access memory (RAM) device 140, a non-volatile memory (NVM) device 142, and a read-only memory (ROM) device 144. In addition, the processors 122 are connected to one or more input/output (I/O) controllers 146 and a communications circuit 148. In an embodiment, the communications circuit 148 provides an interface that allows wireless or wired communication with one or more external devices or networks, such as the LAN discussed above.

Controller 38 includes operation control methods embodied in application code (e.g., program instructions executable by a processor to cause the processor to perform operations). These methods are embodied in computer instructions written to be executed by processors 122, typically in the form of software. The software is encoded in any language, including, but not limited to, assembly language, VHDL (Verilog Hardware Description Language), VHSIC HDL (Very High Speed Integrated Circuit Hardware Description Language), Fortran (formula translation), C, C++, C#, Objective-C, Visual C++, Java, ALGOL (algorithmic language), BASIC (beginners all-purpose symbolic instruction code), visual BASIC, ActiveX, HTML (HyperText Markup Language), Python, Ruby and any combination or derivative of at least one of the foregoing.

It should be appreciated that while embodiments herein describe the 3D coordinate measurement device as being a laser scanner, this is for example purposes and the claims should not be so limited. In other embodiments, the 3D coordinate measurement device is another type of system that measures a plurality of points on surfaces (i.e., generates a point cloud), such as but not limited to a triangulation scanner, a structured light scanner, a photogrammetry device, a light detection and ranging (LIDAR) device, and/or the like including combinations and/or multiples thereof, for example.

FIG. 5 is a schematic illustration of a processing system 500 for predictive collision analysis based on inputs from a gaming controller 530 according to one or more embodiments described herein. The processing system 500 receives 3D data, such as from a 3D coordinate measurement device 520, and/or image data, such as from a camera 521 (e.g., a panoramic camera, a 360 degree camera, and/or the like including combinations and/or multiples thereof). The 3D data and the image data is captured in or in proximity to an environment 522, such as scene of an incident (e.g., a collision between vehicles). It should be appreciated that one or multiple 3D coordinate measurement devices are used in various embodiments. According to one or more embodiments described herein, the 3D coordinate measurement device 520 is used to take multiple scans. For example, the 3D coordinate measurement device 520 captures first scan data at a first scan point and then be moved to a second scan point, where the 3D coordinate measurement device 520 captures second scan data.

It should further be appreciated that while embodiments herein refer to the predictive collision analysis being performed on or within an electronic model of the environment that is created using a scanning device, such as 3D coordinate measurement device 520 for example, this is for example purposes and the claims should not be so limited. In other embodiments, the electronic model is generated using a commercial data source, such as Google Earth® for example, where the electronic model is temporally acquired at a different point(s) in time from the collision. In some embodiments, the electronic model is generated at different temporal points using a variety of methods, including but not limited to satellite images, aircraft photogrammetry, aircraft mounted LIDAR, or ground vehicle mounted LIDAR systems.

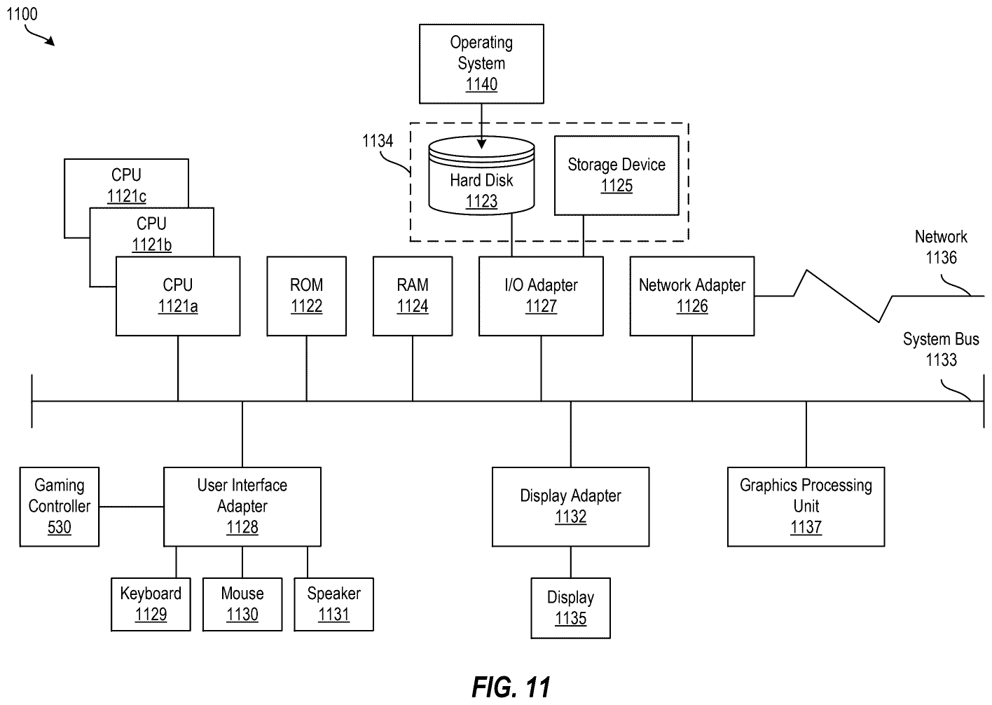

The processing system 500 is any suitable computing device, such as a laptop computer, a desktop computer, a smartphone, a tablet computer, and/or the like, including combinations and/or multiples thereof. FIG. 11 depicts a processing system 1100, which is an example of the processing system 500. As shown in FIG. 5, the processing system 500 includes a processing device 502 (e.g., one or more of the processing devices 1121 of FIG. 11), a system memory 504 (e.g., the RAM 1124 and/or the ROM 1122 of FIG. 11), a network adapter 505 (e.g., the network adapter 1126 of FIG. 11), a data store 508, a display 510, sensor(s), a data capture engine 512, a prediction property engine 514, and an prediction/simulation analysis engine 516.

The various components, modules, engines, etc. described regarding FIG. 5 (e.g., the data capture engine 512, the prediction property engine 514, and the prediction/simulation analysis engine 516) are implemented as instructions stored on a computer-readable storage medium, as hardware modules, as special-purpose hardware (e.g., application specific hardware, application specific integrated circuits (ASICs), application specific special processors (ASSPs), field programmable gate arrays (FPGAs), as embedded controllers, hardwired circuitry, etc.), or as some combination or combinations of these. According to aspects of the present disclosure, the engine(s) described herein is a combination of hardware and programming. The programming is processor executable instructions stored on a tangible memory, and the hardware includes the processing device 502 for executing those instructions. Thus, the system memory 504 stores program instructions that when executed by the processing device 502 implement the engines described herein. Other engines are also utilized to include other features and functionality described in other examples herein.

The network adapter 505 enables the processing system 500 to transmit data to and/or receive data from other sources, such as the 3D coordinate measurement device 520 and/or the camera 521. For example, the processing system 500 receives 3D data (e.g., a data set that includes a plurality of three-dimensional coordinates of the environment 522) from the 3D coordinate measurement devices 520 directly and/or via a network 507. The 3D data from the 3D coordinate measurement device 520 is stored in the data store 508 of the processing system 500 as 3D data 509a, which is used to display a point cloud on the display 510. As another example, the processing system 500 receives image data (e.g., panoramic images of the environment 522) from the camera 521 directly and/or via the network 507. The image data from the cameras 521 is stored in the data store 508 of the processing system 500 as image data 509b, which is displayed on the display 510.

The network 507 represents any one or a combination of different types of suitable communications networks such as, for example, cable networks, public networks (e.g., the Internet), private networks, wireless networks, cellular networks, or any other suitable private and/or public networks. Further, the network 507 has any suitable communication range associated therewith and includes, for example, global networks (e.g., the Internet), metropolitan area networks (MANs), wide area networks (WANs), local area networks (LANs), or personal area networks (PANs). In addition, the network 507 includes any type of medium over which network traffic is carried including, but not limited to, coaxial cable, twisted-pair wire, optical fiber, a hybrid fiber coaxial (HFC) medium, microwave terrestrial transceivers, radio frequency communication mediums, satellite communication mediums, or any combination thereof.

The processing system 500 also is communicatively coupled to a gaming controller 530. The gaming controller 530 is any suitable controller used to provide input, such as to a video game. Although gaming controllers are conventionally used to provide input to video games, one or more embodiments described herein provides for using a gaming controller to provide inputs to a predictive collision analysis. Non-limiting examples of gaming controllers include a steering wheel, steering wheel with associated pedals (e.g., accelerator pedal, brake pedal, clutch pedal), a keyboard, a mouse, a game pad, a joystick, a yoke and throttle assembly for an aircraft, and/or the like including combinations and/or multiples thereof.

Conventionally, setting up predictive collision analyses is a challenging and time consuming process, especially if vehicle steering, acceleration, and/or braking are involved. For example, velocity, acceleration, deceleration, and steering (e.g., vector) data is conventionally entered manually at different positions along a travel path of a vehicle. As a result, this manual setup process takes significant time and makes it difficult to create a natural and realist travel path for vehicles involved in the analysis. In an effort to cure this and other shortcomings, one or more embodiments described herein uses inputs from the gaming controller 530 to support predictive collision analysis. According to one or more embodiments described herein, the gaming controller 530 is used to set up prediction properties for a predictive collision analysis. The gaming controller 530 is used to set the prediction parameters for a travel path of a virtual vehicle to simplify setting realistic and natural settings for speed, acceleration, deceleration, steering along a path, and/or the like including combinations and/or multiples thereof. For example, a user “drives” a virtual vehicle as part of the predictive collision analysis in a desired manner to set prediction parameters as desired. The gaming controller 530 generates signals (e.g., signal 532) based on the user manipulating the gaming controller 530, and the signals are used to define the prediction properties by the prediction property engine 514. Those prediction properties are then used by the prediction/simulation analysis engine 516 to perform the predictive collision analysis.

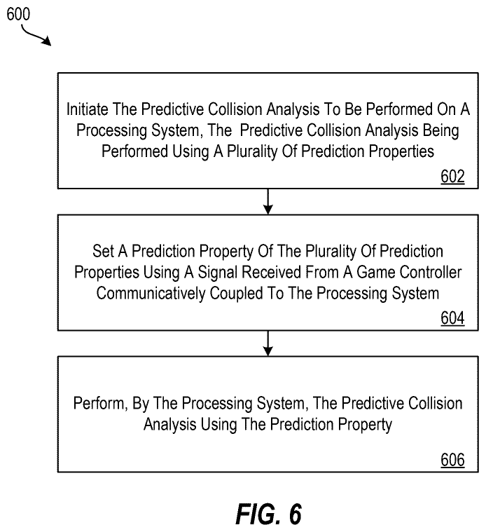

With continued reference to FIG. 5, the features and functionality of the data capture engine 512, the prediction property engine 514, and the prediction/simulation analysis engine 516 are now described in more detail with reference to the following figures. For example, FIG. 6 depicts a flow diagram of a method 600 for predictive collision analysis based on inputs from the gaming controller 530 according to one or more embodiments described herein. The method 600 is performed by any suitable system and/or device, such as the processing system 500 of FIG. 5, the processing system 1100 of FIG. 11, and/or the like including combinations and/or multiples thereof. The method 600 is now described with reference to FIGS. 5 and 7A-10 but is not so limited.

At block 602, the processing system 500 the prediction/simulation analysis engine 516 initiates the predictive collision analysis to be performed on the processing system 500. The predictive collision analysis uses a virtual environment corresponding to the environment 522 and includes a virtual vehicle (or multiple virtual vehicles). The predictive collision analysis is performed using a plurality of prediction properties, which are defined using the prediction property engine 514. Prediction properties define the operating parameters for the predictive collision analysis. For example, prediction properties define features of the environment, features of one or more vehicles, and/or other features. Non-limiting examples of features of the environment include weather conditions, time of day, type of road surface, road conditions, and/or the like including combinations and/or multiples thereof. Non-limiting examples of features of one or more vehicles include velocity, acceleration, direction of travel, lane of travel, and/or the like including combinations and/or multiples thereof.

One or more of the prediction properties are defined using the gaming controller 530. For example, at block 604, the processing system 500, using the prediction property engine 514, sets a prediction property of the plurality of prediction properties using a signal received from the gaming controller 530. As described herein, the gaming controller 530 is any suitable used to provide input, such as to a video game.

According to one or more embodiments described herein, the gaming controller 530 is an electronic steering wheel communicatively coupled to the processing system 500. As used herein, the term “electronic steering wheel” refers to a device that simulates a steering wheel of an automobile. In other words, the electronic steering wheel is a generally round device that rotates about a central axis. In some embodiments, the electronic steering wheel is smaller or larger than an actual automobile steering wheel. In some embodiments, the electronic steering wheel includes haptic feedback mechanisms to increase the accuracy or realism of the simulation.

In such an embodiment, the prediction property engine 514 sets the prediction property using a signal (e.g., the signal 532) received from the electronic steering wheel. According to one or more embodiments described herein, a user manipulates the electronic steering wheel to cause the electronic steering wheel to generate the signal. For example, if the user turns the electronic steering wheel counter-clockwise, the electronic steering wheel generates a signal indicative of a left maneuver of the virtual vehicle. The user controls the degree of the turn, the speed of the turn, and/or the like including combinations and/or multiples thereof, by how the user manipulates the electronic steering wheel. The prediction property is dynamic in that it changes, such as responsive to the user manipulating the electronic steering wheel, during the predictive collision analysis. For example, the steering angle prediction property indicates that the virtual vehicle is traveling “straight” until the user manipulates the electronic steering wheel to cause a “left turn” by turning the electronic steering wheel counter-clockwise, at which point the steering angle prediction property changes.

According to one or more embodiments described herein, additional prediction properties are set. For example, an electronic pedal (e.g., a brake pedal, an accelerator pedal, a clutch pedal, and/or the like including combinations and/or multiples thereof) are used to generate an additional signal that is used to set another prediction property. A user could, for example, set an acceleration prediction property by manipulating (e.g., applying pressure to or releasing pressure from) an accelerator pedal and/or a braking prediction property (e.g., applying pressure to or releasing pressure from) by manipulating a brake pedal. These additional prediction properties are also dynamic and change during the predictive collision analysis responsive to user action.

According to one or more embodiments described herein, the gaming controller 530 includes a keyboard to generate a first signal and a pointing device to generate a second signal. In such an embodiment, the prediction property engine 514 sets a first prediction property using a first signal received from the keyboard and/or sets a second prediction property using a second signal received from the pointing device. It should be appreciated that the keyboard and the pointing device are separate devices or an integral device. As an example, the pointing device is a computer mouse separate from the keyboard. As another example, the pointing device is a trackpad integral to the keyboard. The user manipulates the keyboard and pointing device to operate a virtual vehicle during the predictive collision analysis. For example, the user could control the direction, velocity, and/or acceleration of the virtual vehicle using the pointing device (e.g., move left to cause the virtual vehicle to turn left, move right to cause the virtual vehicle to turn right, move forward to increase forward speed (or decrease reverse speed), move backwards to decrease forward speed (or increase reverse speed), and/or the like including combinations and/or multiples thereof). As another example, the user could control the direction, velocity, and/or acceleration of the virtual vehicle using the keyboard, such as by manipulating arrow keys on the keyboard. It should be appreciated that many different types of inputs on keyboards and pointing devices are possible.

At block 606, the processing system 500 using the prediction/simulation analysis engine 516 performs the predictive collision analysis using the prediction property from block 604. For example, the prediction/simulation analysis engine 516 generates a virtual environment corresponding to the environment 522. The virtual environment includes, for example, a virtual vehicle. The user manipulates the gaming controller to set prediction parameter(s) as described. The prediction parameter(s) are used to perform the predictive collision analysis, which causes the virtual vehicle to behave, within the virtual environment, as intended by the user based on the set prediction parameter(s). The predictive collision analysis includes performing collision modeling, tire force modeling, and/or the like including combinations and/or multiples thereof, using the set prediction parameter(s).

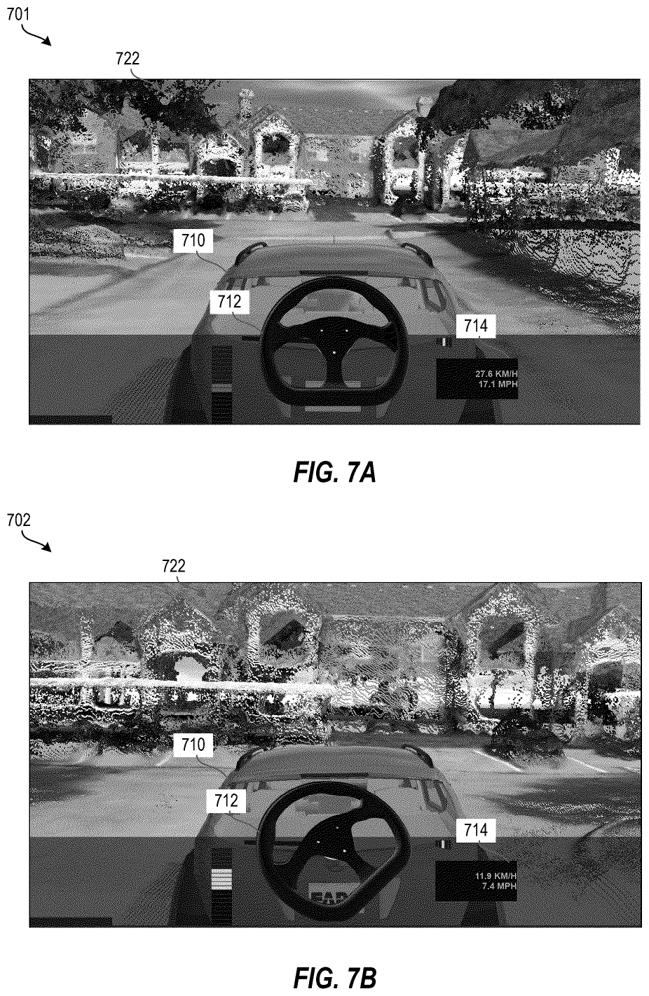

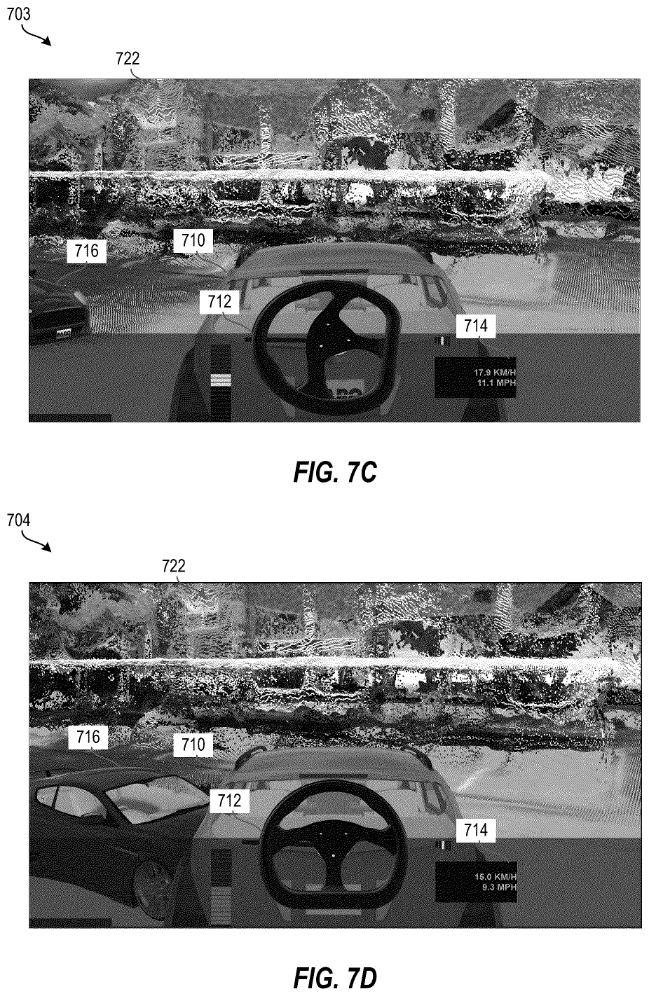

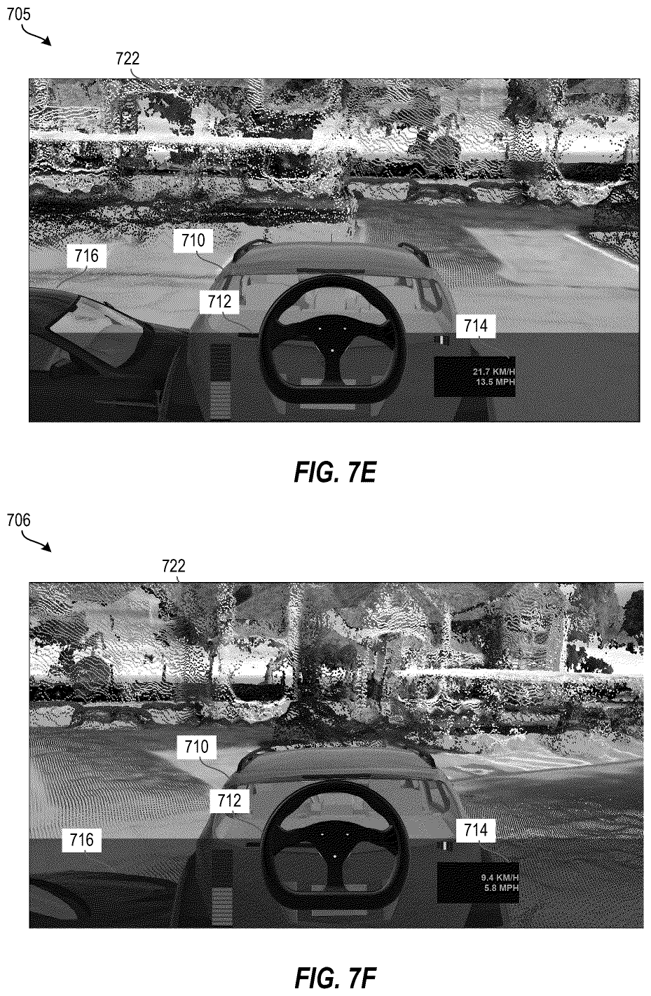

According to one or more embodiments described herein, the method 600 includes generating a real-time display of the predictive collision analysis. The real-time display provides a visual indication of the prediction property. FIGS. 7A-10 are now described regarding the real-time display. For example, FIGS. 7A-10 are interfaces showing a real-time display of the predictive collision analysis according to one or more embodiments described herein.

FIGS. 7A, 7B, 7C, 7D, 7E, and 7F depict interfaces 701, 702, 703, 704, 705, and 706, respectively, that show a real-time display of the predictive collision analysis. The interfaces 701-706 are from a point of view behind a virtual vehicle 710 that is navigating within a virtual environment 722. The interfaces 701-706 also show a virtual representation 712 of a steering wheel that corresponds to the gaming controller 530. When the gaming controller 530 inputs a command, the virtual representation 712 updates in real-time (or near real-time) on the interfaces 701-706. For example, where the electronic gaming controller 530 is an electronic steering wheel, the virtual representation 712 turns within the interfaces 701-706 responsive to corresponding turns of the electronic steering wheel. This provides valuable feedback to a user manipulating the electronic steering wheel to show how the prediction parameter(s) are being set (e.g., during block 604). Additionally, the interfaces 701-706 also show a speedometer 714 (shown in both metric (KM/H) and imperial (MPH) units) that corresponds to the speed of the virtual vehicle 710. Interfaces 703-706 also show another virtual vehicle 716 that, in interfaces 704-706, is shown to collide with the virtual vehicle 710.

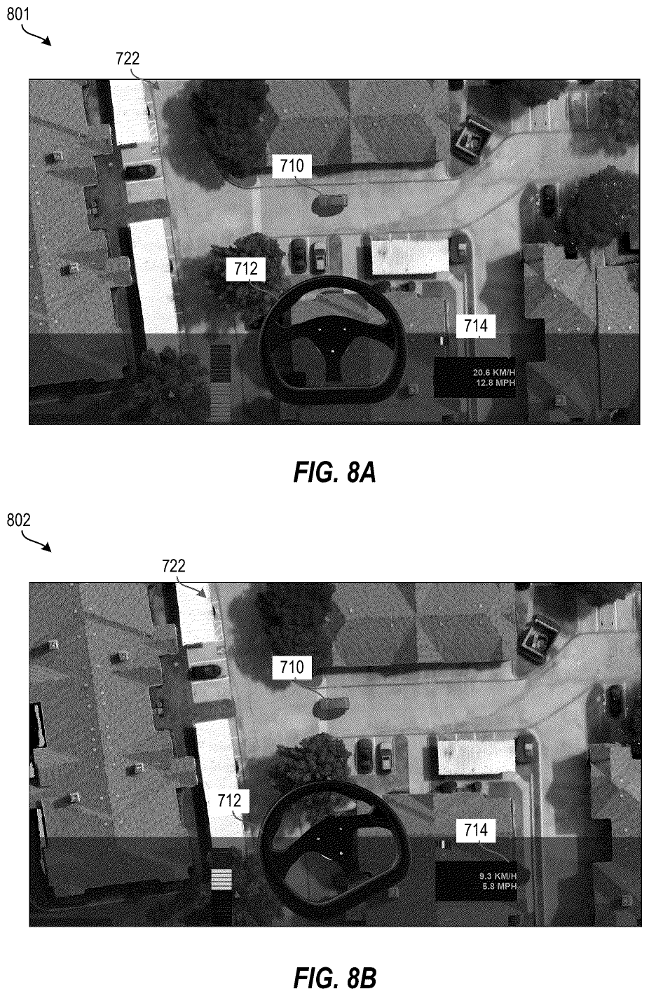

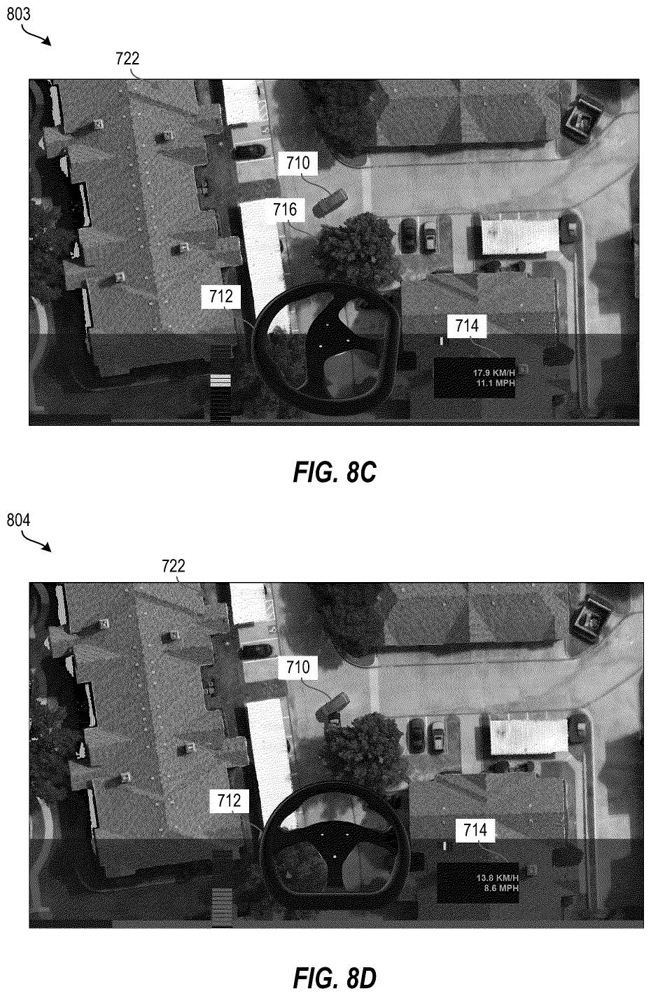

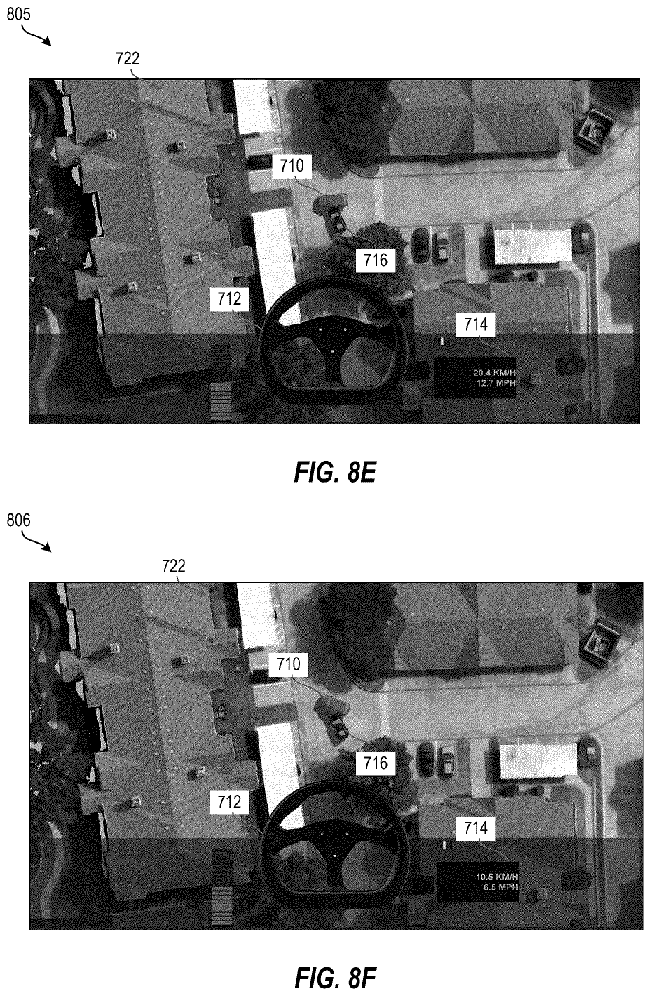

FIGS. 8A, 8B, 8C, 8D, 8E, and 8F depict interfaces 801, 802, 803, 804, 805, and 806, respectively, that correspond to the real-time display of the predictive collision analysis shown in FIGS. 7A-7F. However, in FIGS. 8A-8F, the field of view has been changed to be a bird's eye view above the virtual vehicle 710. In this example, like in the example of FIGS. 7A-7F, when the gaming controller 530 inputs a command, the virtual representation 712 updates in real-time (or near real-time) on the interfaces 801-806.

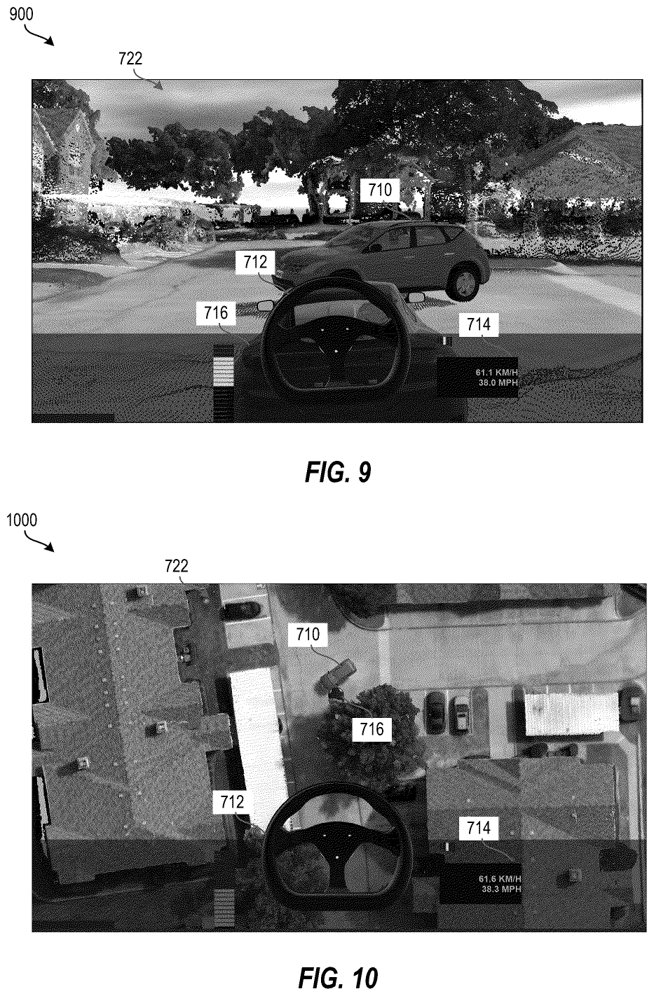

Other fields of view are also possible, such as from behind the other virtual vehicle 716 (e.g., the interface 900 of FIG. 9), from above the other virtual vehicle 716 (e.g., the interface 1000 of FIG. 10), and/or the like including combinations and/or multiples thereof. According to one or more embodiments described herein, the user of the predictive collision analysis defines a point-of-view of the real-time display. For example, the user defines the point-of-view to be within the virtual vehicle, to be above the virtual vehicle, to be a bird's eye view of the virtual environment, and/or the like including combinations and/or multiples thereof. The user defines or selects the point of view and/or modifies or manipulates the point of view (e.g., rotate, shift, zoom, etc.).

As shown in the examples of FIGS. 7A-10, where the gaming controller 530 is an electronic steering wheel, the real-time display provides a visual indication (e.g., the virtual representation 712) of a movement of the electronic steering wheel responsive to a user manipulating the electronic steering wheel. That is, a virtual steering wheel shown on the display 510 (or another suitable display) moves in relation to a movement that the user provides to the electronic steering wheel (e.g., the virtual steering wheel turns clockwise responsive to the user turning the electronic steering wheel clockwise). This is seen, for example, by comparing the virtual representation 712 across FIGS. 7A-7F.

According to one or more embodiments described herein, the predictive collision analysis is performed using 3D data about the environment (e.g., the 3D data 509a about the environment 522). For example, the processing system 500 uses the 3D data to generate the virtual environment 722 corresponding to the environment 522 for display on the display 510 (or another suitable display, such as a heads-up display). With continued reference to FIG. 6, according to one or more embodiments described herein, the method 600 includes using a 3D coordinate measurement device to collect the 3D data as described herein. According to an embodiment, the 3D coordinate measurement device (e.g., the 3D coordinate measurement device 520) is a laser scanner (e.g., the laser scanner 20). According to one or more embodiments described herein, the laser scanner includes a scanner processing system including a scanner controller; a housing; and a 3D scanner disposed within the housing and operably coupled to the scanner processing system, the 3D scanner having a light source, a beam steering unit, a first angle measuring device, a second angle measuring device, and a light receiver, the beam steering unit cooperating with the light source and the light receiver to define a scan area, the light source and the light receiver configured to cooperate with the scanner processing system to determine a first distance to a first object point based at least in part on a transmitting of a light by the light source and a receiving of a reflected light by the light receiver, the 3D scanner configured to cooperate with the scanner processing system to determine 3D coordinates of the first object point based at least in part on the first distance, a first angle of rotation, and a second angle of rotation.

According to one or more embodiments described herein, the display 510 is a heads-up display worn by the user. For example, the display 510 is a virtual reality headset. The user wears the heads-up display while using the gaming controller 530, for example. The heads-up display is communicatively coupled to the processing system 500 via a wired and/or wireless connection.

According to one or more embodiments described herein, the gaming controller 530 provides force feedback to the user. For example, as the predictive collision analysis progresses, if the virtual vehicle the user is operating collides with another object, the gaming controller 530 provides force feedback to the user indicative of the collision. If the user commands the vehicle to turn to the left but doing so encounters resistance, the resistance is communicated to the user via force feedback on the gaming controller 530, for example.

Additional processes are also included, and it should be understood that the process depicted in FIG. 6 represents an illustration, and that other processes are added or existing processes are removed, modified, or rearranged without departing from the scope of the present disclosure.

It is understood that one or more embodiments described herein is capable of being implemented in conjunction with any other type of computing environment now known or later developed. For example, FIG. 11 depicts a block diagram of a processing system 1100 for implementing the techniques described herein. In accordance with one or more embodiments described herein, the processing system 1100 is an example of a cloud computing node of a cloud computing environment. In examples, processing system 1100 has one or more central processing units (“processors” or “processing resources” or “processing devices”) 1121a, 1121b, 1121c, etc. (collectively or generically referred to as processor(s) 1121 and/or as processing device(s)). In aspects of the present disclosure, each processor 1121 includes a reduced instruction set computer (RISC) microprocessor. Processors 1121 are coupled to system memory (e.g., random access memory (RAM) 1124) and various other components via a system bus 1133. Read only memory (ROM) 1122 is coupled to system bus 1133 and includes a basic input/output system (BIOS), which controls certain basic functions of processing system 1100.

Further depicted are an input/output (I/O) adapter 1127 and a network adapter 1126 coupled to system bus 1133. I/O adapter 1127 is a small computer system interface (SCSI) adapter that communicates with a hard disk 1123 and/or a storage device 1125 or any other similar component. I/O adapter 1127, hard disk 1123, and storage device 1125 are collectively referred to herein as mass storage 1134. The operating system 1140 for execution on processing system 1100 is stored in mass storage 1134. The network adapter 1126 interconnects system bus 1133 with an outside network 1136 enabling processing system 1100 to communicate with other such systems.

A display (e.g., a display monitor) 1135 is connected to system bus 1133 by display adapter 1132, which includes a graphics adapter to improve the performance of graphics intensive applications and a video controller. In one aspect of the present disclosure, adapters 1126, 1127, and/or 1132 are connected to one or more I/O buses that are connected to system bus 1133 via an intermediate bus bridge (not shown). Suitable I/O buses for connecting peripheral devices such as hard disk controllers, network adapters, and graphics adapters typically include common protocols, such as the Peripheral Component Interconnect (PCI). Additional input/output devices are shown as connected to system bus 1133 via user interface adapter 1128 and display adapter 1132. A keyboard 1129, mouse 1130, and speaker 1131 are interconnected to system bus 1133 via user interface adapter 1128, which includes, for example, a Super I/O chip integrating multiple device adapters into a single integrated circuit. According to one or more embodiments described herein, the gaming controller 530 is connected to the system bus 1133 via the user interface adapter 1128.

In some aspects of the present disclosure, processing system 1100 includes a graphics processing unit 1137. Graphics processing unit 1137 is a specialized electronic circuit designed to manipulate and alter memory to accelerate the creation of images in a frame buffer intended for output to a display. In general, graphics processing unit 1137 is very efficient at manipulating computer graphics and image processing, and has a highly parallel structure that makes it more effective than general-purpose CPUs for algorithms where processing of large blocks of data is done in parallel.

Thus, as configured herein, processing system 1100 includes processing capability in the form of processors 1121, storage capability including system memory (e.g., RAM 1124), and mass storage 1134, input means such as keyboard 1129 and mouse 1130, and output capability including speaker 1131 and display 1135. In some aspects of the present disclosure, a portion of system memory (e.g., RAM 1124) and mass storage 1134 collectively store the operating system 1140 to coordinate the functions of the various components shown in processing system 1100.

In addition to one or more of the features described herein, or as an alternative, further embodiments of the method includes that a user manipulates the electronic steering wheel to cause the electronic steering wheel to generate the first signal.

In addition to one or more of the features described herein, or as an alternative, further embodiments of the method includes that the first prediction property is dynamic and changes during the predictive collision analysis responsive to changes to the first signal received from the electronic steering wheel.

In addition to one or more of the features described herein, or as an alternative, further embodiments of the method includes setting a second prediction property of the plurality of prediction properties using a second signal received from a first electronic pedal communicatively coupled to the processing system, wherein the predictive collision analysis is further performed using the second prediction property.

In addition to one or more of the features described herein, or as an alternative, further embodiments of the method includes that a user manipulates the first electronic pedal to cause the first electronic pedal to generate the second signal.

In addition to one or more of the features described herein, or as an alternative, further embodiments of the method includes that the second prediction property is dynamic and changes during the predictive collision analysis responsive to changes to the second signal received from the first electronic pedal.

In addition to one or more of the features described herein, or as an alternative, further embodiments of the method includes setting a third prediction property of the plurality of prediction properties using a third signal received from a second electronic pedal communicatively coupled to the processing system, wherein the predictive collision analysis is further performed using the third prediction property.

In addition to one or more of the features described herein, or as an alternative, further embodiments of the method includes that a user manipulates the second electronic pedal to cause the second electronic pedal to generate the third signal.

In addition to one or more of the features described herein, or as an alternative, further embodiments of the method includes that the third prediction property is dynamic and changes during the predictive collision analysis responsive to changes to the third signal received from the second electronic pedal.

In addition to one or more of the features described herein, or as an alternative, further embodiments of the method includes that the predictive collision analysis is performed using three-dimensional (3D) data of an environment.

In addition to one or more of the features described herein, or as an alternative, further embodiments of the method includes collecting the 3D data of the environment using a 3D coordinate measurement device.

In addition to one or more of the features described herein, or as an alternative, further embodiments of the method includes that the 3D coordinate measurement device is a laser scanner that includes a scanner processing system including a scanner controller; a housing; and a 3D scanner disposed within the housing and operably coupled to the scanner processing system, the 3D scanner having a light source, a beam steering unit, a first angle measuring device, a second angle measuring device, and a light receiver, the beam steering unit cooperating with the light source and the light receiver to define a scan area, the light source and the light receiver configured to cooperate with the scanner processing system to determine a first distance to a first object point based at least in part on a transmitting of a light by the light source and a receiving of a reflected light by the light receiver, the 3D scanner configured to cooperate with the scanner processing system to determine 3D coordinates of the first object point based at least in part on the first distance, a first angle of rotation, and a second angle of rotation.

In addition to one or more of the features described herein, or as an alternative, further embodiments of the method includes generating a real-time display of the predictive collision analysis, wherein the real-time display provides a visual indication of a movement of the electronic steering wheel responsive to a user manipulating the electronic steering wheel.

In addition to one or more of the features described herein, or as an alternative, further embodiments of the method includes that the real-time display is displayed on a display of the processing system.

In addition to one or more of the features described herein, or as an alternative, further embodiments of the method includes that the real-time display is displayed on a heads-up display worn by the user while manipulating the electronic steering wheel, wherein the head-up display is communicatively coupled to the processing system.

In addition to one or more of the features described herein, or as an alternative, further embodiments of the method includes that the user defines a point-of-view of the real-time display.

In addition to one or more of the features described herein, or as an alternative, further embodiments of the method includes providing force feedback, via the electronic steering wheel, to a user responsive to performing the predictive collision analysis. It will be appreciated that one or more embodiments described herein may be embodied as a system, method, or computer program product and may take the form of a hardware embodiment, a software embodiment (including firmware, resident software, micro-code, etc.), or a combination thereof. Furthermore, one or more embodiments described herein may take the form of a computer program product embodied in one or more computer readable medium(s) having computer readable program code embodied thereon.

The term “about” is intended to include the degree of error associated with measurement of the particular quantity based upon the equipment available at the time of filing the application. For example, “about” can include a range of ±8% or 5%, or 2% of a given value.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

While the disclosure is provided in detail in connection with only a limited number of embodiments, it should be readily understood that the disclosure is not limited to such disclosed embodiments. Rather, the disclosure can be modified to incorporate any number of variations, alterations, substitutions or equivalent arrangements not heretofore described, but which are commensurate with the spirit and scope of the disclosure. Additionally, while various embodiments of the disclosure have been described, it is to be understood that the exemplary embodiment(s) may include only some of the described exemplary aspects. Accordingly, the disclosure is not to be seen as limited by the foregoing description, but is only limited by the scope of the appended claims.

What is claimed is:

1. A computer-implemented method for performing a predictive collision analysis using three-dimensional (3D) data of an environment, the computer-implemented method comprising:
initiating the predictive collision analysis to be performed on a processing system, the predictive collision analysis being performed using a plurality of prediction properties that define operating parameters of the predictive collision analysis;
wherein the plurality of prediction properties comprise at least a first prediction property and a second prediction property;
setting the first prediction property of the plurality of prediction properties using a first signal received from an electronic steering wheel communicatively coupled to the processing system;
performing, by the processing system, the predictive collision analysis using the first prediction property and the second prediction property;
generating a real-time display of the predictive collision analysis; and
receiving a signal from a gaming controller based on input from a user that defines a point-of-view of the real-time display.

2. The computer-implemented method of claim 1, wherein the user manipulates the electronic steering wheel to cause the electronic steering wheel to generate the first signal.

3. The computer-implemented method of claim 1, wherein the first prediction property is dynamic and changes during the predictive collision analysis responsive to changes to the first signal received from the electronic steering wheel.

4. The computer-implemented method of claim 1, further comprising:
setting the second prediction property of the plurality of prediction properties using a second signal received from a first electronic pedal communicatively coupled to the processing system,
wherein the predictive collision analysis is further performed using the second prediction property.

5. The computer-implemented method of claim 4, wherein the user manipulates the first electronic pedal to cause the first electronic pedal to generate the second signal.

6. The computer-implemented method of claim 4, wherein the second prediction property is dynamic and changes during the predictive collision analysis responsive to changes to the second signal received from the first electronic pedal.

7. The computer-implemented method of claim 4, further comprising:
setting a third prediction property of the plurality of prediction properties using a third signal received from a second electronic pedal communicatively coupled to the processing system,
wherein the predictive collision analysis is further performed using the third prediction property.

8. The computer-implemented method of claim 7, wherein the user manipulates the second electronic pedal to cause the second electronic pedal to generate the third signal.

9. The computer-implemented method of claim 7, wherein the third prediction property is dynamic and changes during the predictive collision analysis responsive to changes to the third signal received from the second electronic pedal.

10. The computer-implemented method of claim 1, further comprising collecting the 3D data of the environment using a 3D coordinate measurement device.

11. The computer-implemented method of claim 10, wherein the 3D coordinate measurement device is a laser scanner.

12. The computer-implemented method of claim 11, wherein the laser scanner comprises:
a scanner processing system including a scanner controller;
a housing; and
a 3D scanner disposed within the housing and operably coupled to the scanner processing system, the 3D scanner having a light source, a beam steering unit, a first angle measuring device, a second angle measuring device, and a light receiver, the beam steering unit cooperating with the light source and the light receiver to define a scan area, the light source and the light receiver cooperating with the scanner processing system to determine a distance to an object point based at least in part on a transmitting of a light by the light source and a receiving of a reflected light by the light receiver, the 3D scanner cooperating with the scanner processing system to determine 3D coordinates of the object point based at least in part on the distance, a first angle of rotation, and a second angle of rotation.

13. The computer-implemented method of claim 1, wherein the real-time display provides a visual indication of a movement of the electronic steering wheel responsive to the user manipulating the electronic steering wheel.

14. The computer-implemented method of claim 1, wherein the real-time display is displayed on a display of the processing system.

15. The computer-implemented method of claim 1, wherein the real-time display is displayed on a heads-up display worn by the user while manipulating the electronic steering wheel.

16. The computer-implemented method of claim 15, wherein the heads-up display is communicatively coupled to the processing system.

17. The computer-implemented method of claim 1, further comprising providing force feedback, via the electronic steering wheel, to the user responsive to performing the predictive collision analysis.

18. A system comprising:
a gaming controller to generate a signal;
a processing system communicatively coupled to the gaming controller to receive the signal from the gaming controller, the processing system comprising:
a memory comprising computer readable instructions; and
a processing device for executing the computer readable instructions, the computer readable instructions controlling the processing device to perform operations for performing a predictive collision analysis using three-dimensional (3D) data of an environment, the operations comprising:
initiating the predictive collision analysis to be performed with the processing system, the predictive collision analysis being performed using a plurality of prediction properties that define operating parameters of the predictive collision analysis;
setting a prediction property of the plurality of prediction properties using the signal generated by the gaming controller; and
performing, by the processing system, the predictive collision analysis using the prediction property; and
a laser scanner used to collect the 3D data of the environment, wherein the laser scanner comprises:
a scanner processing system including a scanner controller;
a housing; and
a 3D scanner disposed within the housing and operably coupled to the scanner processing system, the 3D scanner having a light source, a beam steering unit, a first angle measuring device, a second angle measuring device, and a light receiver, the beam steering unit cooperating with the light source and the light receiver to define a scan area, the light source and the light receiver cooperating with the scanner processing system to determine a distance to an object point based at least in part on a transmitting of a light by the light source and a receiving of a reflected light by the light receiver, the 3D scanner cooperating with the scanner processing system to determine 3D coordinates of the object point based at least in part on the distance, a first angle of rotation, and a second angle of rotation.

19. A system comprising:
a keyboard to generate a first signal;
a pointing device to generate a second signal; and
a processing system communicatively coupled to the keyboard to receive the first signal from the keyboard and communicatively coupled to the mouse to receive the second signal from the mouse, the processing system comprising:
a memory comprising computer readable instructions; and
a processing device for executing the computer readable instructions, the computer readable instructions controlling the processing device to perform operations for performing a predictive collision analysis using three-dimensional data of an environment, the operations comprising:
initiating the predictive collision analysis to be performed with the processing system, the predictive collision analysis being performed using a plurality of prediction properties that define operating parameters of the predictive collision analysis;
setting a first prediction property of the plurality of prediction properties using the first signal generated by the keyboard, the first signal being generated by a user manipulating keys of the keyboard to cause the first signal to mimic a first behavior of the vehicle;
setting a second prediction property of the plurality of prediction properties using the second signal generated by the pointing device, the second signal being generated by the user manipulating the pointing device to cause the second signal to mimic a second behavior of the vehicle;
performing, by the processing system, the predictive collision analysis using the first prediction property and the second prediction property; and
generating a real-time display of the predictive collision analysis, wherein the real-time display provides a visual indication of a movement of an electronic steering wheel responsive to at least one of the first signal generated by the keyboard and the second signal generated by the pointing device.

20. The system of claim 19, further comprising a laser scanner used to collect the three-dimensional data of the environment.
